(19) United States
(12) Patent Application Publication
(10) Pub. No.: US 2026/0173659 A1
(43) Pub. Date: Jun. 18, 2026

(54) Display Device

(71) Applicant: LG Display Co.,Ltd., Seoul (KR)

(72) Inventors: Jihyang Yoon, Ulsan (KR); YunHo Kook, Goyang-si (KR); Jonghan Park, Seoul (KR); Seungpyo Hong, Paju-si (KR)

(21) Appl. No.: 19/370,514

(22) Filed: Oct. 27, 2025

(30) Foreign Application Priority Data
Dec. 13, 2024 (KR) 10-2024-0186431

(51) Int. Cl. H10K 59/122; H10K 59/12; H10K 59/80; H10K 102/00

(52) U.S. Cl. CPC H10K 59/122; H10K 59/1201; H10K 59/80521; H10K 59/873; H10K 2102/351

(57) ABSTRACT

A display device presented herein includes a substrate with a plurality of subpixels, a planarization layer on the substrate and comprising an opening portion and a protruding portion, a first electrode that covers a part of the opening portion and a part of the protruding portion, a bank that exposes a part of a top surface of the first electrode, an organic layer on the top surface of the first electrode, a second electrode on the bank and the organic layer, a first encapsulation layer on the second electrode, and a second encapsulation layer on the first encapsulation layer. The protruding portion comprises an inclined portion and a flat portion extending from the inclined portion. The first encapsulation layer comprises a plurality of first protrusions disposed in an area that overlaps at least a part of the inclined portion and a part of the flat portion.

### CROSS-REFERENCE TO RELATED APPLICATION

The present application claims priority to Republic of Korea Patent Application No. 10-2024-0186431 filed on December 13, 2024, which is incorporated by reference in its entirety.

### BACKGROUND

### Field

The present disclosure relates to a display device, and more particularly, to a display device with improved light extraction efficiency.

### Description of the Related Art

Recently, display devices, which visually display electrical information signals, are being rapidly developed in accordance with the full-fledged entry into the information era. Various studies are being continuously conducted to develop a variety of display devices which are thin and lightweight, consume low power, and have improved performance.

Among the various display devices, an organic light-emitting display device refers to a display device that autonomously emits light. Unlike a liquid crystal display device, the organic light-emitting display device does not require a separate light source and thus may be manufactured as a lightweight, thin display device. In addition, the display device is advantageous in terms of power consumption because the display device operates at a low voltage. Further, the display device is expected to be adopted in various fields because the display device is also excellent in implementation of colors, response speeds, viewing angles, and contrast ratios (CRs).

### SUMMARY

An object to be achieved by the present disclosure is to provide a display device having a structure capable of improving light extraction efficiency.

Another object to be achieved by the present disclosure is to provide a display device with improved visibility.

Still another object to be achieved by the present disclosure is to provide a display device capable of reducing permeation of moisture or oxygen into a light-emitting element.

Objects of the present disclosure are not limited to the above-mentioned objects, and other objects, which are not mentioned above, can be clearly understood by those skilled in the art from the following descriptions.

According to an aspect of the present disclosure, there is provided a display device. The display device includes a substrate including a plurality of subpixels. The display device further includes a planarization layer disposed on the substrate and comprising an opening portion and a protruding portion. The display device further includes a first electrode disposed to cover a part of the opening portion and a part of the protruding portion. The display device further includes a bank disposed to expose a part of a top surface of the first electrode. The display device further includes an organic layer disposed on the top surface of the first electrode. The display device further includes a second electrode disposed on the bank and the organic layer. The display device further includes a first encapsulation layer disposed on the second electrode. The display device further includes a second encapsulation layer disposed on the first encapsulation layer. The protruding portion comprises an inclined portion and a flat portion extending from the inclined portion. The first encapsulation layer comprises a plurality of first protrusions disposed in an area that overlaps at least a part of the inclined portion and a part of the flat portion.

According to another aspect of the present disclosure, there is provided a display device. The display device includes a substrate comprising a plurality of subpixels. The display device further includes a planarization layer disposed on the substrate and comprising an opening portion and a protruding portion. The display device further includes a first electrode disposed to cover the opening portion and the protruding portion. The display device further includes a bank disposed on a part of a top surface of the first electrode. The display device further includes an organic layer disposed on the first electrode. The display device further includes a second electrode disposed on the bank and the organic layer. The display device further includes a first encapsulation layer disposed on the second electrode. The display device further includes a second encapsulation layer disposed on the first encapsulation layer. At least one of the plurality of subpixels comprises a first light-emitting area, a second light-emitting area configured to surround the first light-emitting area, a third light-emitting area configured to surround the second light-emitting area and a non-light-emitting area configured to surround the third light-emitting area. The first encapsulation layer comprises a plurality of protrusions. At least some of the protrusions overlap at least a part of the third light-emitting area and at least a part of the non-light-emitting area.

Other detailed matters of the embodiments are included in the detailed description and the drawings.

According to one or more embodiments of the present disclosure, the planarization layer has the opening portion corresponding to the light-emitting area, thereby improving the light extraction efficiency and operating the display device with low power consumption in terms of the reduction in power consumption.

According to one or more embodiments of the present disclosure, the surface of the encapsulation layer made of an organic film is flat in the area with a level difference, such that the permeation of moisture or oxygen into the light-emitting element may be suppressed, and the encapsulation layer is not visually recognized, thereby improving the visibility.

According to one or more embodiments of the present disclosure, a light emitting device representing an emission portion of a subpixel of a plurality of subpixels of a display device includes a first electrode, a bank on a portion of the first electrode, an organic layer on the first electrode, at least a part of the organic layer in direct contact with a part of the first electrode in an area where the bank exposes the first electrode, a second electrode on the organic layer and the bank, and one or more encapsulation layers on the second electrode. At least one of the bank, the organic layer, the second electrode, and the one or more encapsulation layers includes a plurality of protrusions positioned outside of the area where at least the part of the organic layer is in direct contact with the part of the first electrode.

Acording to one or more embodiments, the one or more encapsulation layers includes a first encapsulation layer on the second electrode and in direct contact with the second electrode. The the first encapsulation layer includes a first plurality of protrusions of the plurality of protrusions.

According to one or more embodiments, the the bank includes a second plurality of protrusions of the plurality of protrusions, and the the second electrode includes a third plurality of protrusions of the plurality of protrusions.

According to one or more embodiments, the the organic layer includes a fourth plurality of protrusions of the plurality of protrusions.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic configuration view of a display device according to one or more embodiments of the present disclosure.

FIG. 2 is an enlarged view of area Z in FIG. 1.

FIG. 3 is a cross-sectional view taken along line A-B in FIG. 2.

FIG. 4 is a cross-sectional view schematically illustrating a partial area of a display area of a display device according to one or more embodiments of the present disclosure.

FIGS. 5A and 5B are views schematically illustrating a process of forming a second encapsulation layer in the display device according to one or more embodiments of the present disclosure.

FIG. 6 is a view illustrating a contact angle between a second encapsulation layer material and a plurality of first protrusions in the display device according to one or more embodiments of the present disclosure.

FIGS. 7A and 7B are views schematically illustrating a process of forming a second encapsulation layer in a display device according to one or more embodiments of the present disclosure.

FIG. 8 is a cross-sectional view schematically illustrating a partial area of a display area of a display device according to one or more embodiments of the present disclosure.

FIG. 9 is a cross-sectional view schematically illustrating a partial area of a display area of a display device according to one or more embodiments of the present disclosure.

FIG. 10 is a view illustrating a layered structure of a first encapsulation layer in FIG. 9.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to embodiments of the present disclosure will be described in detail with reference to accompanying drawings.

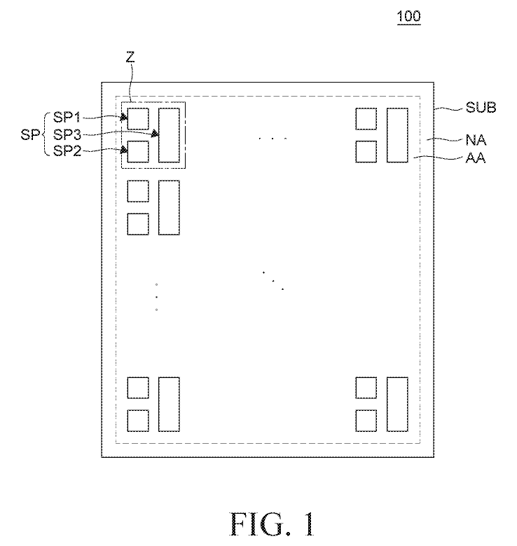

FIG. 1 is a schematic configuration view of a display device according to one or more embodiments of the present disclosure.

With reference to FIG. 1, a display device 100 includes a substrate SUB including a display area AA and a non-display area NA. The display device 100 may be implemented as a top-emission type display device, but the present disclosure is not limited thereto.

The display area AA refers to an area of the display device 100 in which images are displayed. Various display elements and various driving elements for operating the display elements may be disposed in the display area AA. For example, the display element may include an organic light-emitting element (OLED). In addition, various driving elements such as transistors, capacitors, lines, and the like, which are configured to operate the display elements, may be disposed in the display area AA.

A plurality of subpixels SP may be included in the display area AA. The subpixel SP is a minimum unit that constitutes a screen. The plurality of subpixels SP may each include a display element and a drive circuit. The plurality of subpixels SP may emit light beams having different wavelengths. For example, the plurality of subpixels SP may include a first subpixel SP1 configured to emit red light, a second subpixel SP2 configured to emit green light, and a third subpixel SP3 configured to emit blue light. The first subpixel SP1, the second subpixel SP2, and the third subpixel SP3 may be sequentially arranged in the display area AA. However, the present disclosure is not limited thereto.

In addition, FIG. 1 illustrates that at least one of the first subpixel SP1, the second subpixel SP2, or the third subpixel SP3 has an area different from those of the other subpixels. However, the present disclosure is not limited thereto. That is, the first subpixel SP1, the second subpixel SP2, and the third subpixel SP3 may have the same area. In addition, FIG. 1 illustrates that the first subpixel SP1, the second subpixel SP2, and the third subpixel SP3 each have a quadrangular shape. However, the present disclosure is not limited thereto. That is, the first subpixel SP1, the second subpixel SP2, and the third subpixel SP3 may each have a circular shape, a polygonal shape, or the like.

The drive circuit of the subpixel SP is a circuit for controlling an operation of the display element. For example, the drive circuit may include driving elements such as a transistor and a capacitor. However, the present disclosure is not limited thereto.

The non-display area NA refers to an area in which no image is displayed. Various constituent elements for operating the plurality of subpixels SP disposed in the display area AA may be disposed in the non-display area NA. For example, drive ICs, flexible films, and the like, which are configured to supply signals for operating the plurality of subpixels SP, may also be disposed.

As illustrated in FIG. 1, the non-display area NA may be an area that surrounds the display area AA. However, the present disclosure is not limited thereto. For example, the non-display area NA may be an area extending from the display area AA.

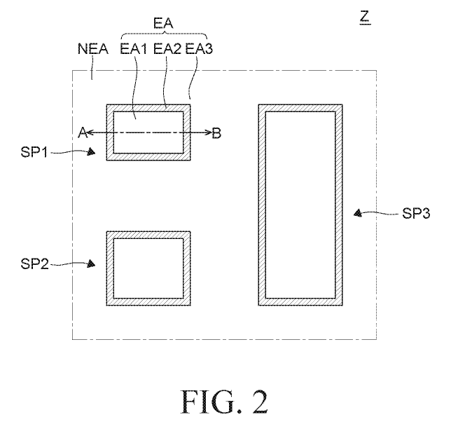

FIG. 2 is an enlarged view of area Z in FIG. 1.

With reference to FIG. 2, the plurality of subpixels SP may each include a light-emitting area EA.

The plurality of subpixels SP may include the light-emitting areas EA configured to emit light beams with different colors.

At least one light-emitting area EA may include a plurality of light-emitting areas EA1, EA2, and EA3. For example, the light-emitting area EA may include a first light-emitting area EA1, a second light-emitting area EA2, and a third light-emitting area EA3.

In this case, the second light-emitting area EA2 may be disposed to surround the first light-emitting area EA1. The third light-emitting area EA3 may be disposed to surround the second light-emitting area EA2.

Luminance of the second light-emitting area EA2 may be lower than luminance of the first light-emitting area EA1 and luminance of the third light-emitting area EA3. The luminance of the third light-emitting area EA3 may be lower than the luminance of the first light-emitting area EA1.

A non-light-emitting area NEA may be disposed between the light-emitting areas EA of each of the plurality of subpixels SP.

The non-light-emitting area NEA may be disposed to surround the third light-emitting area EA3 of each of the subpixels.

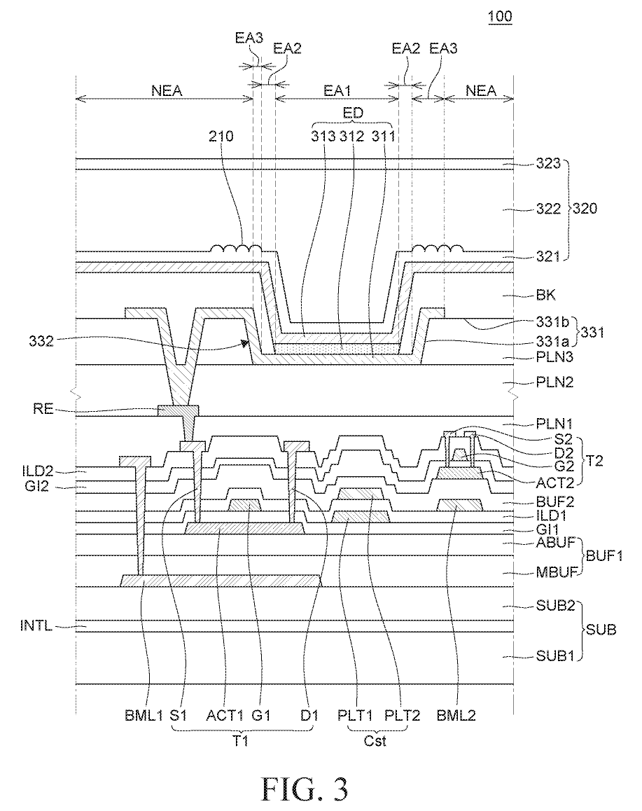

FIG. 3 is a cross-sectional view taken along line A-B in FIG. 2.

With reference to FIG. 3, the display device 100 may include the substrate SUB, a first buffer layer BUF1 on the substrate SUB, and a plurality of transistors T1 and T2, a storage capacitor Cst, and various electrodes or signal lines disposed on the first buffer layer BUF1.

The substrate SUB may include a first substrate SUB1 and a second substrate SUB2 and include an intermediate film INTL disposed between the first substrate SUB1 and the second substrate SUB2.

The first substrate SUB1 and the second substrate SUB2 may each be made of glass or a plastic material having flexibility. In case that the first substrate SUB1 and the second substrate SUB2 are made of a plastic material, the first substrate SUB1 and the second substrate SUB2 may be made of polyimide (PI), for example. However, the present disclosure is not limited thereto.

The intermediate film INTL may be an inorganic film and block the permeation. However, the present disclosure is not limited thereto.

The first buffer layer BUF1 may be a single film or a multilayer film. In case that the first buffer layer BUF1 is a multilayer film, the first buffer layer BUF1 may include a multi-buffer layer MBUF and an active buffer layer ABUF.

The multi-buffer layer MBUF and the active buffer layer ABUF may each be configured as a single layer made of silicon nitride (SiNx) or silicon oxide (SiOx) or a multilayer made of silicon nitride (SiNx) or silicon oxide (SiOx). However, the present disclosure is not limited thereto.

A first light-blocking layer BML1 may be disposed between the first buffer layer BUF1 and the substrate SUB.

The first light-blocking layer BML1 may overlap the entirety or a part of a first active layer ACT1. The first light-blocking layer BML1 may serve as a light shield configured to block light introduced from below. In this case, the first light-blocking layer BML1 may be electrically connected to a first source electrode S1.

The first light-blocking layer BML1 may include an electrically conductive material. For example, a first light-blocking layer 102a may be made of any one of molybdenum (Mo), aluminum (Al), chromium (Cr), gold (Au), titanium (Ti), nickel (Ni), neodymium (Nd), copper (Cu), and an alloy of two or more of these materials. Alternatively, the first light-blocking layer 102a may be configured as a multilayer made of any one of molybdenum (Mo), aluminum (Al), chromium (Cr), gold (Au), titanium (Ti), nickel (Ni), neodymium (Nd), copper (Cu), and an alloy of two or more of these materials. However, the present disclosure is not limited thereto.

The plurality of transistors T1 and T2, the storage capacitor Cst, and various electrodes or signal lines may be disposed on the first buffer layer BUF1.

For example, the plurality of transistors T1 and T2 formed on the first buffer layer BUF1 may be made of the same material and disposed on the same layer. Alternatively, as illustrated in FIG. 3, among the plurality of transistors T1 and T2, a first transistor T1 and a second transistor T2 may be made of different materials and positioned on different layers.

The plurality of transistors T1 and T2 may include the first transistor T1 and the second transistor T2.

The first transistor T1 may include the first active layer ACT1, a first gate electrode G1, the first source electrode S1, and a first drain electrode D1.

The second transistor T2 may include a second active layer ACT2, a second gate electrode G2, a second source electrode S2, and a second drain electrode D2.

The second active layer ACT2 of the second transistor T2 may be disposed to be higher than the first active layer ACT1 of the first transistor T1.

The first buffer layer BUF1 may be disposed below the first active layer ACT1 of the first transistor T1, and a second buffer layer BUF2 may be disposed below the second active layer ACT2 of the second transistor T2.

A second light-blocking layer BML2 may be disposed below the second active layer ACT2.

The second light-blocking layer BML2 may include an electrically conductive material. For example, the first light-blocking layer 102a may be made of any one of molybdenum (Mo), aluminum (Al), chromium (Cr), gold (Au), titanium (Ti), nickel (Ni), neodymium (Nd), copper (Cu), and an alloy of two or more of these materials. Alternatively, the first light-blocking layer 102a may be configured as a multilayer made of any one of molybdenum (Mo), aluminum (Al), chromium (Cr), gold (Au), titanium (Ti), nickel (Ni), neodymium (Nd), copper (Cu), and an alloy of two or more of these materials. However, the present disclosure is not limited thereto.

That is, the first active layer ACT1 of the first transistor T1 may be positioned on the first buffer layer BUF1, and the second active layer ACT2 of the second transistor T2 may be positioned on the second buffer layer BUF2. In this case, the second buffer layer BUF2 may be positioned to be higher than the first buffer layer BUF1.

The first active layer ACT1 of the first transistor T1 may be disposed on the first buffer layer BUF1, and a first gate insulation film GI1 may be disposed on the first active layer ACT1 of the first transistor T1.

The first active layer ACT1 may be made of oxide semiconductor. The first active layer ACT1 may be made of amorphous silicon (a-Si), polycrystalline silicon (poly-Si), organic semiconductor, or the like.

The first gate insulation film GI1 may be configured as a single layer made of silicon nitride (SiNx) or silicon oxide (SiOx) that is an inorganic material. Alternatively, the first gate insulation film GI1 may be configured as a multilayer made of silicon nitride (SiNx) or silicon oxide (SiOx). However, the present disclosure is not limited thereto.

The second gate electrode G2 of the second transistor T2 may be disposed on the first gate insulation film GI1, and a first interlayer insulation film ILD1 may be disposed on the second gate electrode G2 of the second transistor T2.

The second gate electrode G2 may be made of any one of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. Alternatively, the second gate electrode G2 may be configured as a multilayer made of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. However, the present disclosure is not limited thereto.

The first interlayer insulation film ILD1 may be configured as a single layer made of silicon nitride (SiNx) or silicon oxide (SiOx) that is an inorganic material. Alternatively, the first interlayer insulation film ILD1 may be configured as a multilayer made of silicon nitride (SiNx) or silicon oxide (SiOx). However, the present disclosure is not limited thereto.

The first active layer ACT1 of the first transistor T1 may include a first channel area configured to overlap the first gate electrode G1, a first source connection area positioned at one side of the first channel area, and a first drain connection area positioned at the other side of the first channel area.

The second buffer layer BUF2 may be disposed on the first interlayer insulation film ILD1.

The second buffer layer BUF2 may be configured as a single layer made of silicon nitride (SiNx) or silicon oxide (SiOx) that is an inorganic material. Alternatively, the second buffer layer BUF2 may be configured as a multilayer made of silicon nitride (SiNx) or silicon oxide (SiOx). However, the present disclosure is not limited thereto.

The second active layer ACT2 of the second transistor T2 may be disposed on the second buffer layer BUF2, and a second gate insulation film GI2 may be disposed on the second active layer ACT2.

The second active layer ACT2 may be made of oxide semiconductor. The second active layer ACT2 may be made of amorphous silicon (a-Si), polycrystalline silicon (poly-Si), organic semiconductor, or the like.

The second gate insulation film GI2 may be configured as a single layer made of silicon nitride (SiNx) or silicon oxide (SiOx) that is an inorganic material. Alternatively, the second gate insulation film GI2 may be configured as a multilayer made of silicon nitride (SiNx) or silicon oxide (SiOx). However, the present disclosure is not limited thereto.

The second gate electrode G2 of the second transistor T2 may be disposed on the second gate insulation film GI2, and a second interlayer insulation film ILD2 may be disposed on the second gate electrode G2.

The second gate electrode G2 may be made of any one of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. Alternatively, the second gate electrode G2 may be configured as a multilayer made of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. However, the present disclosure is not limited thereto.

The second interlayer insulation film ILD2 may be configured as a single layer made of silicon nitride (SiNx) or silicon oxide (SiOx) that is an inorganic material. Alternatively, the second interlayer insulation film ILD2 may be configured as a multilayer made of silicon nitride (SiNx) or silicon oxide (SiOx). However, the present disclosure is not limited thereto.

In this case, the second active layer ACT2 of the second transistor T2 may include a second channel area configured to overlap the second gate electrode G2, a second source connection area positioned at one side of the second channel area, and a second drain connection area positioned at the other side of the second channel area.

The first source electrode S1 and the first drain electrode D1 of the first transistor T1 may be disposed on the second interlayer insulation film ILD2. In addition, the second source electrode S2 and the second drain electrode D2 of the second transistor T2 may be disposed on the second interlayer insulation film ILD2.

The first source electrode S1 and the first drain electrode D1 of the first transistor T1 may be respectively connected to the first source connection area and the first drain connection area of the first active layer ACT1 through contact holes of the second interlayer insulation film ILD2, the second gate insulation film GI2, the second buffer layer BUF2, the first interlayer insulation film ILD1, and the first gate insulation film GI1.

The second source electrode S2 and the second drain electrode D2 of the second transistor T2 may be respectively connected to the second source connection area and the second drain connection area of the second active layer ACT2 through contact holes of the second interlayer insulation film ILD2 and the second gate insulation film GI2.

The storage capacitor Cst may include a first capacitor electrode PLT1 and a second capacitor electrode PLT2.

The first source electrode S1, the first drain electrode D1, the second source electrode S2, the second drain electrode D2, the first capacitor electrode PLT1, and the second capacitor electrode PLT2 may each be made of any one of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. Alternatively, the first source electrode S1, the first drain electrode D1, the second source electrode S2, the second drain electrode D2, the first capacitor electrode PLT1, and the second capacitor electrode PLT2 may each be configured as a multilayer made of various metallic materials, for example, molybdenum (Mo), aluminum (Al), chromium (Cr), gold (Au), titanium (Ti), nickel (Ni), neodymium (Nd), copper (Cu), and an alloy of two or more of these metallic materials. However, the present disclosure is not limited thereto.

A planarization layer may be disposed on the first transistor T1 and the second transistor T2.

The planarization layer may include a first planarization layer PLN1, a second planarization layer PLN2, and a third planarization layer PLN3.

The first to third planarization layers PLN1, PLN2, and PLN3 may each be made of one of acrylic resin, epoxy resin, phenolic resin, polyamide-based resin, polyimide-based resin, unsaturated polyester-based resin, polyphenylene-based resin, polyphenylene sulfide-based resin, benzocyclobutene, and photoresist. However, the present disclosure is not limited thereto.

The first planarization layer PLN1 may be disposed on the first transistor T1 and the second transistor T2. That is, the first planarization layer PLN1 may be disposed on the first source electrode S1 and the first drain electrode D1 of the first transistor T1 and the second source electrode S2 and the second drain electrode D2 of the second transistor T2.

A relay electrode RE may be disposed on the first planarization layer PLN1. The relay electrode RE may be an electrode that relays electrical connection between the first source electrode S1 of the first transistor T1 and a first electrode 311 of a light-emitting element ED.

The relay electrode RE may be configured as a single layer or multilayer made of any one of molybdenum (Mo), copper (Cu), titanium (Ti), aluminum (Al), chromium (Cr), gold (Au), nickel (Ni), neodymium (Nd), and an alloy thereof.

The relay electrode RE may be electrically connected to the first source electrode S1 of the first transistor T1 through a contact hole of the first planarization layer PLN1.

The second planarization layer PLN2 may be disposed on the relay electrode RE and the first planarization layer PLN1.

The third planarization layer PLN3 may be disposed on the second planarization layer PLN2. The first electrode 311 of the light-emitting element ED may be electrically connected to the relay electrode RE through contact hole areas of the second and third planarization layers PLN2 and PLN3.

FIG. 3 illustrates a structure in which the second planarization layer PLN2 is disposed on the first planarization layer PLN1, and the third planarization layer PLN3 is disposed on the second planarization layer PLN2. However, the present disclosure is not limited thereto. For example, the third planarization layer PLN3 may be disposed on the first planarization layer PLN1 on the substrate SUB, and only the third planarization layer PLN3 may be disposed on the first planarization layer PLN1.

The third planarization layer PLN3 may include a protruding portion 331 and an opening portion 332.

The opening portion 332 of the third planarization layer PLN3 may expose a part of a top surface of the second planarization layer PLN2.

The opening portion 332 of the third planarization layer PLN3 may be disposed in an area corresponding to the first light-emitting area EA1 and the second light-emitting area EA2.

FIG. 3 illustrates a structure in which the third planarization layer PLN3 includes the opening portion 332 in the area corresponding to the first and second light-emitting areas EA1 and EA2. However, the present disclosure is not limited thereto. For example, a height of the third planarization layer PLN3 disposed in the area corresponding to the first and second light-emitting areas EA1 and EA2 may be lower than a height of the third planarization layer PLN3 disposed in an area (excluding the contact hole area) corresponding to the non-light-emitting area NEA and the third light-emitting area EA3.

The protruding portion 331 of the third planarization layer PLN3 may include an inclined portion 331a, and a flat portion 331b extending from the inclined portion 331a.

The first electrode 311 may be disposed in the opening portion 332 of the third planarization layer PLN3 and disposed in a partial area of the protruding portion 331. Specifically, the first electrode 311 may be disposed in the opening portion 332, disposed on the inclined portion 331a of the protruding portion 331, and disposed in a partial area on the flat portion 331b.

The first electrode 311 may be an anode electrode of the light-emitting element ED.

The first electrode 311 may include a reflective electrode capable of reflecting light.

The first electrode 311 may have a single-layer structure or a multilayer structure. In case that the first electrode 311 has a multilayer structure, the first electrode 311 may include at least one reflective electrode layer and at least one transparent conductive material layer.

The reflective electrode included in the first electrode 311 may include any one of metal, such as aluminum (Al), gold (Au), silver (Ag), copper (Cu), tungsten (W), molybdenum (Mo), chromium (Cr), tantalum (Ta), and titanium (Ti), or an alloy thereof. However, the present disclosure is not limited thereto.

The transparent conductive material included in the first electrode 311 may include at least one of indium tin oxide (ITO), indium zinc oxide (IZO), or indium gallium zinc oxide (IGZO). However, the present disclosure is not limited thereto.

The first electrode 311 may also be disposed in the contact holes provided in the second and third planarization layers PLN2 and PLN3.

The first electrode 311 may be in contact with a top surface of the second planarization layer PLN2 in an area corresponding to the concave portion 332 of the third planarization layer PLN3.

The first electrode 311 may be in contact with the relay electrode RE, which is disposed below the second planarization layer PLN2, through the contact holes provided in the second and third planarization layers PLN2 and PLN3.

A bank BK may be disposed on the third planarization layer PLN3 and the first electrode 311.

The bank BK may include an organic material. However, the present disclosure is not limited thereto. The bank BK may include an inorganic material. In addition, FIG. 3 illustrates a structure in which the bank BK is configured as a single layer. However, the present disclosure is not limited thereto. The bank BK may be configured as a multilayer.

The bank BK may include a bank hole through which a part of a top surface of the first electrode 311 is exposed. That is, one bank hole formed in the bank BK may overlap a part of one first electrode 311.

The bank BK may also overlap a part of the concave portion 332 of the third planarization layer PLN3. Specifically, the bank BK may be disposed on a side surface of the third planarization layer PLN3 in the concave portion 332 of the third planarization layer PLN3 and also be disposed on a part of a top surface of the first electrode 311.

The bank BK may also overlap the contact hole area. Specifically, the bank BK may fill contact hole areas formed in the second and third planarization layers PLN2 and PLN3. In the contact hole area, a height of the bank BK may be larger than a height of the bank BK that partially overlaps the opening portion 332.

An organic layer 312 of the light-emitting element ED may be disposed in the bank hole through which a part of the top surface of the first electrode 311 is exposed. That is, the organic layer 312 may be disposed on the top surface of the first electrode AE that does not overlap the bank BK.

The organic layer 312 may be disposed in the opening portion 332 of the third planarization layer PLN3.

The organic layer 312 may include at least one light-emitting layer and at least one common layer.

The light-emitting layer is an organic layer configured to emit light with a particular color. Different light-emitting layers may be disposed in the plurality of subpixels SP, respectively. The identical light-emitting layers may be disposed in the entire plurality of subpixels SP. For example, in the case in which the different light-emitting layers are disposed in the plurality of subpixels SP, respectively, a red light-emitting layer may be disposed in a red subpixel, a green light-emitting layer may be disposed in a green subpixel, and a blue light-emitting layer may be disposed in a blue subpixel. In the case in which the identical light-emitting layers are disposed in the entire plurality of subpixels SP, the light emitted from the light-emitting layer may be converted into the light with various colors by a separate optical conversion layer, a color filter, or the like.

The common layer is an organic layer disposed to improve luminous efficiency of the light-emitting layer. The identical common layers may be formed over the plurality of subpixels SP. That is, the common layers of the plurality of subpixels SP may be made of the same material and simultaneously formed through the same process. The common layer may include a positive hole injecting layer, a positive hole transporting layer, an electron transporting layer, an electron injecting layer, a charge generating layer, and the like. However, the present disclosure is not limited thereto.

A second electrode 313 of the light-emitting element ED may be disposed on the organic layer 312 and the bank BK.

The second electrode 313 may be a cathode electrode of the light-emitting element ED.

The second electrode 313 may be configured as a layer including a transparent conductive material. In addition, the second electrode 313 may be configured as a layer including a semi-transparent electrode made of metal or metal alloy.

Meanwhile, one subpixel may include the plurality of light-emitting areas EA1, EA2, and EA3. For example, one subpixel may include the first light-emitting area EA1, the second light-emitting area EA2 configured to surround the first light-emitting area EA1, and the third light-emitting area EA3 configured to surround the second light-emitting area EA2.

The first light-emitting area EA1 may be an area in which the bank is not disposed on the first electrode 311. That is, the first light-emitting area EA1 of the subpixel may be an area in which the bank hole, through which a part of the top surface of the first electrode 311 is exposed, is positioned in the opening portion 332 of the third planarization layer PLN3.

The second light-emitting area EA2 may include an area in which the opening portion 332 of the third planarization layer PLN3 and the bank BK overlap.

The third light-emitting area EA3 may include an area corresponding to the inclined portion 331a of the protruding portion 331 of the third planarization layer PLN3. Alternatively, the third light-emitting area EA3 may include an area in which the first electrode 311 is disposed on the inclined portion 331a.

An encapsulation layer 320 may be disposed on the second electrode 313 of the light-emitting element ED.

The encapsulation layer 320 may be disposed in a shape that covers the light-emitting elements ED.

The encapsulation layer 320 may be a layer that suppresses the permeation of moisture or oxygen into the light-emitting element ED disposed below the encapsulation layer 320. In particular, the encapsulation layer 320 may inhibit moisture or oxygen from permeating into the organic layer 312 including the light-emitting layer.

The encapsulation layer 320 may include a first encapsulation layer 321, a second encapsulation layer 322, and a third encapsulation layer 323.

The first encapsulation layer 321 may be disposed on the second electrode 313 of the light-emitting element ED, the second encapsulation layer 322 may be disposed on the first encapsulation layer 321, and the third encapsulation layer 323 may be disposed on the second encapsulation layer 322.

The first encapsulation layer 321 and the third encapsulation layer 323 may be configured as inorganic films, and the second encapsulation layer 322 may be configured as an organic film. Because the second encapsulation layer 322 is configured as an organic film, the second encapsulation layer 322 may also serve as a planarization layer.

In case that the second encapsulation layer 322 is not disposed because of a level difference or the like caused by components disposed below the second encapsulation layer 322, moisture or oxygen may permeate into the light-emitting element ED. In addition, in case that a top surface of the second encapsulation layer 322 is not flat even though the second encapsulation layer 322 is disposed, there may occur a problem in that a non-flat area of the top surface of the second encapsulation layer 322 is visually recognized.

Therefore, the first encapsulation layer 321 may include a plurality of first protrusions 210 in at least a partial area of the display area AA.

Specifically, the first protrusions 210 may be disposed in at least a part of the third light-emitting area EA3 and a partial area of the non-light-emitting area NEA.

In addition, some of the first protrusions 210 may overlap at least a part of the inclined portion 331a of the third planarization layer PLN3, and some of the remaining first protrusions 210 may overlap a part of the flat portion 331b of the third planarization layer PLN3.

The plurality of first protrusions 210 may have various cross-sectional shapes.

For example, FIG. 3 illustrates that the cross-sectional shape of the first protrusion 210 is a semicircular shape. However, the present disclosure is not limited thereto. The cross-sectional shape of the first protrusion 210 may be a shape such as a semielliptical shape or a polygonal shape. In addition, the plurality of first protrusions 210 may have the same shape, or at least two of the plurality of first protrusions 210 may have different shapes.

At least some of the first protrusions 210 may be disposed to surround a periphery of the bank hole. Therefore, the spreading characteristics of a material of the second encapsulation layer 322 during a process of forming the second encapsulation layer 322 may be improved, such that the second encapsulation layer 322 may be disposed even in an area in which there is a level difference caused by the opening portion 332 of the third planarization layer PLN3. Therefore, the top surface of the second encapsulation layer 322 may be provided flat.

Even the inside of the bank hole is also filled with the second encapsulation layer 322, thereby suppressing the permeation of moisture or oxygen into the light-emitting element ED disposed below the second encapsulation layer 322.

In addition, because the top surface of the second encapsulation layer 322 is provided flat, a top surface of the third encapsulation layer 323 disposed on the second encapsulation layer 322 may also be flat. Therefore, it is possible to suppress a deterioration in visibility characteristics of the display device caused by a decrease in flatness of the second and third encapsulation layers 322 and 323.

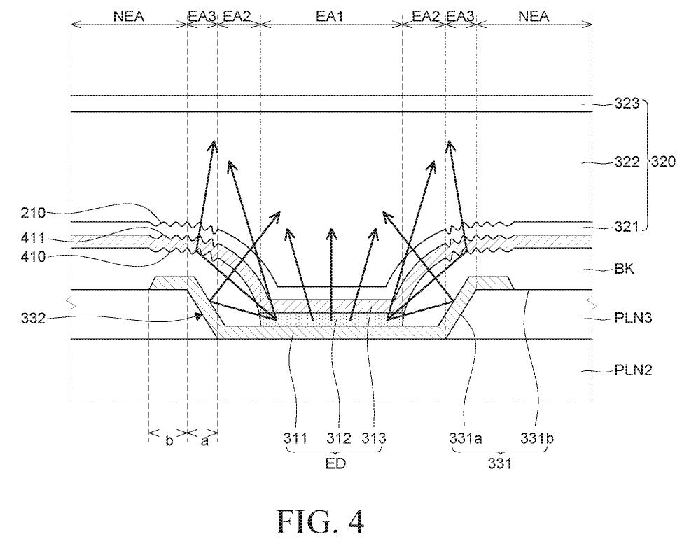

FIG. 4 is a cross-sectional view schematically illustrating a partial area of a display area of a display device according to one or more embodiments of the present disclosure. The partial area of the display area of the display device illustrated in FIG. 4 can be also referred to as a light emitting device and represents a light emitting portion of a subpixel of the display device.

A light emitting device in FIG. 4 is substantially identical in configuration to a light emitting portion of the display device in FIG. 3, except that a plurality of second protrusions 410 are provided on a surface of the bank BK, and a plurality of third protrusions 411 are provided on the second electrode 313. Therefore, repeated descriptions of the identical components will be omitted.

With reference to FIG. 4, the third planarization layer PLN3 having the protruding portion 331 and at least one opening portion 332 may be disposed on the second planarization layer PLN2.

The first electrode 311 of the light-emitting element ED may be disposed on a part of the top surface of the second planarization layer PLN2 and a part of the top surface of the third planarization layer PLN3.

The first electrode 311 may be disposed in the opening portion 332 of the third planarization layer PLN3 and disposed on a part of the inclined portion 331a of the protruding portion 331 of the third planarization layer PLN3 and a part of the flat portion 331b of the protruding portion 331.

The bank BK may be disposed on a part of the top surface of the first electrode 311 and the third planarization layer PLN3.

The bank BK may be disposed in a partial area of the opening portion 332 of the third planarization layer PLN3. The bank BK may be disposed in the opening portion 332 of the third planarization layer PLN3 and expose a part of the top surface of the first electrode 311.

The plurality of second protrusions 410 may be disposed on a part of a top surface of the bank BK.

Specifically, some of the plurality of second protrusions 410 may be disposed in an area corresponding to the inclined portion 331a of the protruding portion 331. Some of the remaining second protrusions 410 may be disposed in an area corresponding to a part of the flat portion 331b of the protruding portion 331. The plurality of second protrusions 410 may overlap the first electrode 311 in an area in which the plurality of second protrusions 410 correspond to a part of the flat portion 331b of the protruding portion 331.

Some of the plurality of second protrusions 410 may be disposed in an area corresponding to the third light-emitting area EA3. Some of the remaining second protrusions 410 may be disposed in an area corresponding to the non-light-emitting area NEA.

The plurality of second protrusions 410 may be disposed to surround a periphery of the second light-emitting area EA2.

The plurality of second protrusions 410, which are disposed in the area corresponding to the third light-emitting area EA3, may reflect some light beams emitted from the light-emitting element ED and allow the reflected light beams to propagate to the outside of the display device 100, thereby improving the luminance of the light-emitting area EA. That is, the plurality of second protrusions 410 may serve to improve the light extraction efficiency of the display device 100.

A first width a, which is a width of the area in which the plurality of second protrusions 410 are disposed to correspond to the inclined portion 331a of the protruding portion 331, may be equal to or larger than a second width b that is a width of the area in which the plurality of second protrusions 410 are disposed to correspond to the flat portion 331b of the protruding portion 331.

A sum of the first width a and the second width b may be 2 µm to 3 µm, and the first width a may be 1 µm to 1.5 µm. Because the sum of the first width a and the second width b is 2 µm to 3 µm, the plurality of first protrusions 210 disposed on the plurality of second protrusions 410 may be designed to be disposed in a part of the third light-emitting area EA3 and a part of the non-light-emitting area NEA.

The plurality of second protrusions 410 may be formed by a process using a mask. For example, the plurality of second protrusions 410 may be formed by a process such as dry etching or photolithography.

A shape of the plurality of second protrusions 410 disposed on the inclined portion 331a of the protruding portion 331 may be identical to a shape of the plurality of second protrusions 410 disposed on the flat portion 331b of the protruding portion 331. However, the present disclosure is not limited thereto.

In case that the shape of the plurality of second protrusions 410 disposed on the inclined portion 331a of the protruding portion 331 is different from the shape of the plurality of second protrusions 410 disposed on the flat portion 331b of the protruding portion 331, a value of centerline average roughness Ra of the plurality of second protrusions 410 disposed on the inclined portion 331a of the protruding portion 331 may be different from a value of centerline average roughness Ra of the plurality of second protrusions 410 disposed on the flat portion 331b of the protruding portion 331.

For example, the value of the centerline average roughness Ra of the plurality of second protrusions 410 disposed on the inclined portion 331a of the protruding portion 331 may be larger than the value of the centerline average roughness Ra of the plurality of second protrusions 410 disposed on the flat portion 331b of the protruding portion 331. When the value of the centerline average roughness Ra increases, the amount of light, which is reflected and changes in path, increases. Therefore, the first electrode 311, which is disposed on the inclined portion 331a of the protruding portion 331, reflects the light, and the plurality of second protrusions 410, which overlaps the inclined portion 331a of the protruding portion 331, reflects the light, thereby improving the luminance of the light-emitting area EA.

However, the display device according to one or more embodiments of the present disclosure is not limited thereto. The plurality of second protrusions 410, which are disposed on the inclined portion 331a of the protruding portion 331, and the plurality of second protrusions 410, which are disposed on the flat portion 331b, only need to have the value of the centerline average roughness Ra of 100 nm to 200 nm.

In case that the value of the centerline average roughness Ra of the plurality of second protrusions 410 is less than 100 nm, the material of the second encapsulation layer 322 cannot sufficiently spread into the bank hole during the process of forming the second encapsulation layer 322. In addition, in case that the value of the centerline average roughness Ra of the plurality of second protrusions 410 is more than 200 nm, the second electrode 313 disposed on the bank BK may be disconnected.

The organic layer 312 of the light-emitting element ED including the light-emitting layer may be disposed in the bank hole and disposed on the first electrode 311.

The second electrode 313 of the light-emitting element ED may be disposed on the organic layer 312 and the bank BK.

The second electrode 313 may include the plurality of third protrusions 411 in an area corresponding to the area in which the plurality of second protrusions 410 of the bank BK are disposed.

The first encapsulation layer 321 may be disposed on the second electrode 313 including the third protrusions 411.

The first encapsulation layer 321 may include the plurality of first protrusions 210. The plurality of first protrusions 210 of the first encapsulation layer 321 may be disposed in an area corresponding to the area in which the second protrusions 410 and the third protrusions 411 are disposed.

Some of the plurality of first protrusions 210, some of the plurality of second protrusions 410, and some of the plurality of third protrusions 411 may overlap the third light-emitting area EA3. In addition, some of the plurality of first protrusions 210, some of the plurality of second protrusions 410, and some of the plurality of third protrusions 411 may overlap the non-light-emitting area NEA.

The plurality of third protrusions 411 and the plurality of first protrusions 210 may be formed along the shape of the plurality of second protrusions 410. Therefore, the value of the centerline average roughness Ra of the plurality of third protrusions 411 and the value of the centerline average roughness Ra of the plurality of first protrusions 210 may be smaller than the value of the centerline average roughness Ra of the plurality of second protrusions 410.

For example, the value of the centerline average roughness Ra of the plurality of second protrusions 410 may be 100 nm to 200 nm. Further, the value of the centerline average roughness Ra of the first protrusions 210 disposed on the plurality of second protrusions 410 may be 80 nm to 170 nm.

Because the value of the centerline average roughness Ra of the plurality of second protrusions 410 is 100 nm to 200 nm, the value of the centerline average roughness Ra of the first protrusions 210 is 80 nm to 170 nm, such that the first encapsulation layer 321 may have surface roughness that may improve the spreading characteristics of the material of the second encapsulation layer 322 during the process of forming the second encapsulation layer 322.

Meanwhile, a part of the light emitted from the light-emitting element ED may propagate toward the adjacent subpixel SP and be trapped in the display device 100 without propagating to the outside of the display device 100. In this case, a loss of light emitted from the light-emitting element ED occurs, and luminous efficiency deteriorates. High power consumption may be required to suppress the above-mentioned problem.

The display device according to one or more embodiments of the present disclosure includes the second light-emitting area EA2 and the third light-emitting area EA3, thereby improving the luminous efficiency and implementing the display device 100 capable of operating with low power consumption.

The second light-emitting area EA2 and the third light-emitting area EA3 may be areas formed as the light emitted from the light-emitting element ED is reflected by the first electrode 311 disposed on the inclined portion 331a of the third planarization layer PLN3.

In addition, the plurality of first protrusions 210, the plurality of second protrusions 410, and the plurality of third protrusions 411 may serve to change paths so that the light emitted from the light-emitting element ED is not trapped in the display device 100.

Specifically, the path of the light, which reaches any one of the plurality of first protrusions 210, the plurality of second protrusions 410, or the plurality of third protrusions 411, may be changed, such that the light may propagate to the outside of the first light-emitting area EA1, the second light-emitting area EA2, or the third light-emitting area EA3. Therefore, the luminance of the first light-emitting area EA1, the second light-emitting area EA2, and the third light-emitting area EA3 may increase.

The second encapsulation layer 322 may be disposed on the first encapsulation layer 321, and the third encapsulation layer 323 may be disposed on the second encapsulation layer 322.

The plurality of first protrusions 210 included in the first encapsulation layer 321 may serve to allow the bank hole to be filled with the material of the second encapsulation layer 322 during the process of forming the second encapsulation layer 322.

In addition, the plurality of first protrusions 210 may serve to allow the top surface of the second encapsulation layer 322 to be formed flat even in the area in which a level difference occurs because of the inclined portion 331a of the protruding portion 331.

In addition, because the bank BK has the plurality of second protrusions 410, a process of forming the plurality of third protrusions 411 and the plurality of first protrusions 210 on the first encapsulation layer 321 and the second electrode 313 disposed on the bank BK may be simplified.

Specifically, the material of the second electrode 313 and the material of the first encapsulation layer 321 are formed along a surface shape of the plurality of second protrusions 410 in the area in which the plurality of second protrusions 410 are disposed. Therefore, it is not necessary to add a process of forming the plurality of third protrusions 411 and the plurality of first protrusions 210 during the process of forming the second electrode 313 and the first encapsulation layer 321.

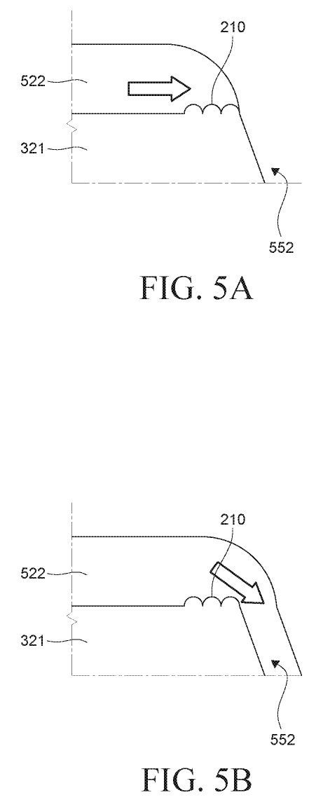

FIGS. 5A and 5B are views schematically illustrating a process of forming the second encapsulation layer in the display device according to one or more embodiments of the present disclosure.

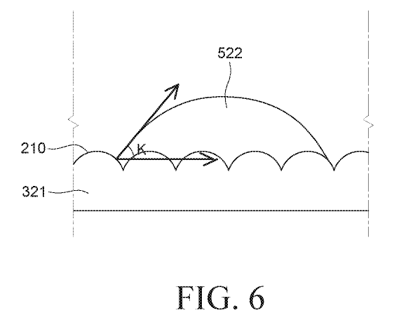

FIG. 6 is a view illustrating a contact angle between the second encapsulation layer material and the plurality of first protrusions in the display device according to one or more embodiments of the present disclosure.

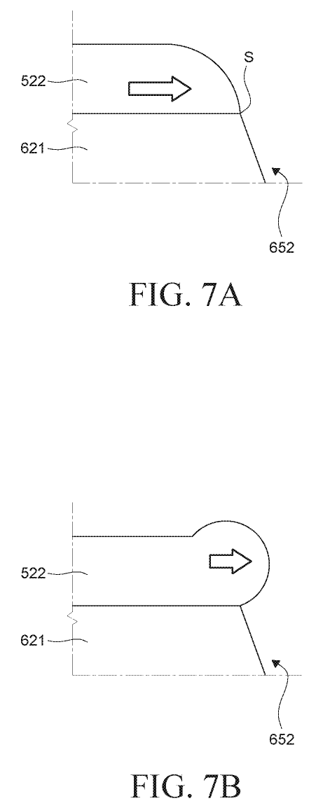

FIGS. 7A and 7B are views schematically illustrating a process of forming a second encapsulation layer in a display device according to one or more embodiments of the present disclosure.

First, with reference to FIGS. 5A and 5B, the first encapsulation layer 321 may include the plurality of first protrusions 210 in a partial area. For example, the first encapsulation layer 321 may include the plurality of first protrusions 210 in at least a partial area of the area of the first encapsulation layer 321 that surrounds an opening portion 552.

In addition, although not illustrated in FIGS. 5A and 5B, the opening portion 552 of the first encapsulation layer 321 may overlap the bank hole in FIGS. 3 and 4.

A second encapsulation layer material 522 may be applied onto the first encapsulation layer 321. The second encapsulation layer material 522 may be an organic material.

The second encapsulation layer material 522 may spread into the opening portion 552 of the first encapsulation layer 321 from the top surface of the first encapsulation layer 321.

The plurality of first protrusions 210 may improve the spreading characteristics of the second encapsulation layer material 522.

In particular, in case that a shape of an outer periphery of the subpixel SP is a shape including a rounded shape, such as a circular shape or an elliptical shape, in a plan view, the spreading characteristics of the second encapsulation layer material 522 may be degraded, and the second encapsulation layer material 522 may not be disposed in a partial area of the subpixel SP.

However, in the display device according to one or more embodiments of the present disclosure, the first encapsulation layer 321 includes the plurality of first protrusions 210, the second encapsulation layer material 522 may be disposed in a desired area regardless of a planar shape of the subpixel SP.

FIGS. 5A and 5B illustrate that a shape of each of the plurality of first protrusions 210 is a semielliptical shape in a cross-sectional view. However, the present disclosure is not limited thereto. The plurality of first protrusions 210 disposed on the first encapsulation layer 321 may have the same overall shape, or the plurality of first protrusions 210 may have different shapes.

With reference to FIG. 6, the plurality of first protrusions 210 may increase an area, in which the second encapsulation layer material 522 is in contact with the surface of the first encapsulation layer 321, and decrease a contact angle k defined with respect to the surface of the first encapsulation layer 321, thereby improving the spreading characteristics.

The plurality of first protrusions 210 disposed to surround the opening portion 552 of the first encapsulation layer 321 may allow the second encapsulation layer material 522 to spread into the opening portion 552 of the first encapsulation layer 321.

Therefore, the opening portion 332 may be filled with the second encapsulation layer material 522 without a defect even though there is a level difference caused by the opening portion 332 of the third planarization layer PLN3. In this case, the configuration in which there is no defect means a configuration in which the top surface of the second encapsulation layer 322 formed by the second encapsulation layer material 522 has a flat shape, and there is no area in which the second encapsulation layer material 522 is not disposed.

With reference to FIGS. 7A and 7B, in case that the second encapsulation layer material 522 is applied onto a first encapsulation layer 621 that does not have a plurality of first protrusions, an opening portion 652 of the first encapsulation layer 621, which does not have the plurality of first protrusions, may not be filled with the second encapsulation layer material 522.

Specifically, a force by which the second encapsulation layer material 522 spreads may decrease at a boundary point between an inclined portion, which is formed by the opening portion 652 of the first encapsulation layer 621 that does not have the plurality of first protrusions, and a flat portion extending from the inclined portion. Therefore, a contact angle singularity S occurs at the boundary point between the flat portion and the inclined portion of the first encapsulation layer 621 that does not have the plurality of first protrusions, which may delay the spread of the second encapsulation layer material 522.

For this reason, in case that the first encapsulation layer 621 does not include the plurality of first protrusions that surround the opening portion 652, a defect may occur in which the bank hole is not filled with the second encapsulation layer material 522.

For example, as illustrated in FIGS. 7A and 7B, the force by which the second encapsulation layer material 522 spreads may decrease even though the first encapsulation layer 621 does not include the plurality of first protrusions, which surround the opening portion 652, and only the components (e.g., the bank) disposed below the first encapsulation layer 621 include a plurality of protrusions. Therefore, the bank hole may not be sufficiently filled with the second encapsulation layer material 522.

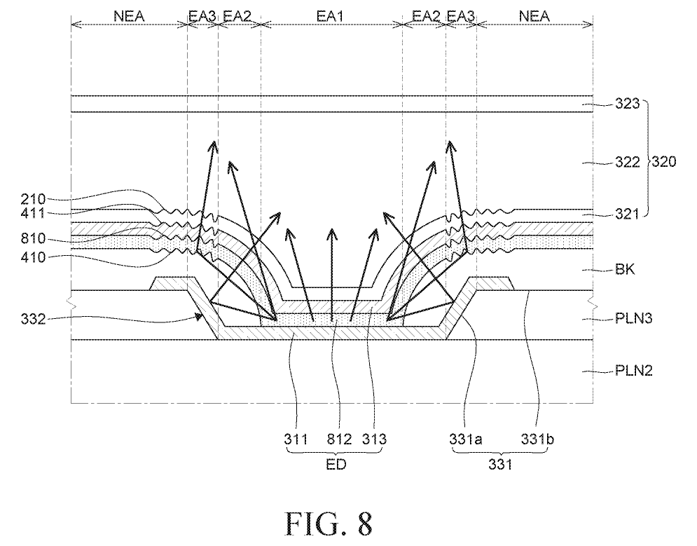

FIG. 8 is a cross-sectional view schematically illustrating a partial area of a display area of a display device according to one or more embodiments of the present disclosure. The partial area of the display area of the display device illustrated in FIG. 8 can be also referred to as a light emitting device and represents a light emitting portion of a subpixel of the display device.

A light emitting device in FIG. 8 is substantially identical in configuration to the light emitting device in FIG. 4, except for a structure in which an organic layer 812 is disposed to extend to the top surface of the bank BK. Therefore, a repeated description will be omitted.

With reference to FIG. 8, the organic layer 812 of the light-emitting element ED may be disposed on the top surface of the first electrode 311 that does not overlap the bank BK in the opening portion 332 of the third planarization layer PLN3. In addition, the organic layer 812 may be disposed to extend to the top surface of the bank BK.

The organic layer 812 may include a plurality of fourth protrusions 810 disposed on the plurality of second protrusions 410.

Some of the plurality of fourth protrusions 810 may overlap the third light-emitting area EA3, and some of the remaining fourth protrusions 810 may overlap a part of the non-light-emitting area NEA.

The plurality of first protrusions 210, the plurality of second protrusions 410, the plurality of third protrusions 411, and the plurality of fourth protrusions 810 may overlap one another.

At least some of the first protrusions 210 may be disposed to surround the periphery of the bank hole. Therefore, the spreading characteristics of the material of the second encapsulation layer 322 during the process of forming the second encapsulation layer 322 may be improved, such that the second encapsulation layer 322 may be disposed even in the area in which there is a level difference caused by the opening portion 332 of the third planarization layer PLN3. Therefore, the top surface of the second encapsulation layer 322 may be provided flat.

Even the inside of the bank hole is also filled with the second encapsulation layer 322, thereby suppressing the permeation of moisture or oxygen into the light-emitting element ED disposed below the second encapsulation layer 322.

In addition, because the top surface of the second encapsulation layer 322 is provided flat, the top surface of the third encapsulation layer 323 disposed on the second encapsulation layer 322 may also be flat. Therefore, it is possible to suppress a deterioration in visibility characteristics of the display device caused by a decrease in flatness of the second and third encapsulation layers 322 and 323.

In addition, because the bank BK has the plurality of second protrusions 410, a process of forming the plurality of fourth protrusions 810, the plurality of third protrusions 411, and the plurality of first protrusions 210 on the organic layer 812, the second electrode 313, and the first encapsulation layer 321 disposed on the bank BK may be simplified.

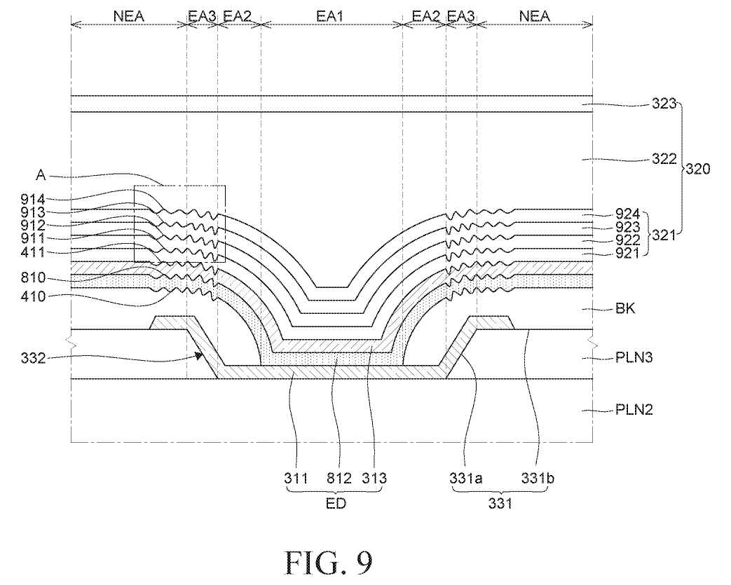

FIG. 9 is a cross-sectional view schematically illustrating a partial area of a display area of a display device according to one or more embodiments of the present disclosure. The partial area of the display area of the display device illustrated in FIG. 9 can be also referred to as a light emitting device and represents a light emitting portion of a subpixel of the display device.

A light emitting device in FIG. 9 is substantially identical in configuration to the light emitting device in FIG. 8, except for a structure in which a first encapsulation layer 321 is configured as a plurality of sub-encapsulation layers 921, 922, 923, and 924. Therefore, a repeated description will be omitted.

With reference to FIG. 9, the first encapsulation layer 321 may be disposed on the light-emitting element ED, and the first encapsulation layer 321 may include the plurality of sub-encapsulation layers 921, 922, 923, and 924. Because the display device has the subpixel having the same structure as the subpixel illustrated in FIG. 8, except that the first encapsulation layer 321 is configured as the plurality of sub-encapsulation layers 921, 922, 923, and 924 instead of being configured as a single encapsulation layer. Therefore, a repeated description will be omitted.

A first sub-encapsulation layer 921 may be disposed on the second electrode 313 of the light-emitting element ED, a second sub-encapsulation layer 922 may be disposed on the first sub-encapsulation layer 921, a third sub-encapsulation layer 923 may be disposed on the second sub-encapsulation layer 922, and a fourth sub-encapsulation layer 924 may be disposed on the third sub-encapsulation layer 923. FIG. 9 illustrates a structure in which the first encapsulation layer 321 is configured as four layers. However, embodiments of the present disclosure are not limited thereto. The first encapsulation layer 321 only needs to be configured as two or more layers.

The second encapsulation layer 322 may be disposed on the fourth sub-encapsulation layer 924 positioned at an uppermost end of the first encapsulation layer 321.

The first sub-encapsulation layer 921, the second sub-encapsulation layer 922, the third sub-encapsulation layer 923, and the fourth sub-encapsulation layer 924 include a plurality of protrusions 911, 912, 913, and 914, respectively.

The plurality of protrusions 911, 912, 913, and 914 of the first sub-encapsulation layer 921, the second sub-encapsulation layer 922, the third sub-encapsulation layer 923, and the fourth sub-encapsulation layer 924 may overlap the plurality of second protrusions 410, the plurality of third protrusions 411, and the plurality of fourth protrusions 810.

That is, the plurality of protrusions 911, 912, 913, and 914 of the first sub-encapsulation layer 921, the second sub-encapsulation layer 922, the third sub-encapsulation layer 923, and the fourth sub-encapsulation layer 924 may overlap the third light-emitting area EA3 and overlap a part of the non-light-emitting area NEA. In addition, the plurality of protrusions 911, 912, 913, and 914 of the first sub-encapsulation layer 921, the second sub-encapsulation layer 922, the third sub-encapsulation layer 923, and the fourth sub-encapsulation layer 924 may overlap the inclined portion 331a of the protruding portion 331 of the third planarization layer PLN3 and overlap a part of the flat portion 331b.

The plurality of protrusions 914 of the fourth sub-encapsulation layer 924 may serve to improve the spreading characteristics of the material of the second encapsulation layer 322 during the process of forming the second encapsulation layer 322. Therefore, even in the area in which a level difference is present, the second encapsulation layer 322 may be disposed, and the top surface of the second encapsulation layer 322 may be provided flat.

Therefore, the second encapsulation layer 322 may be formed without a defect, thereby suppressing a defect of the light-emitting element ED caused by the permeation of moisture or oxygen into the light-emitting element ED. Additionally, the first encapsulation layer 321 may be configured as at least three layers, thereby further suppressing the permeation of moisture or oxygen into the light-emitting element ED.

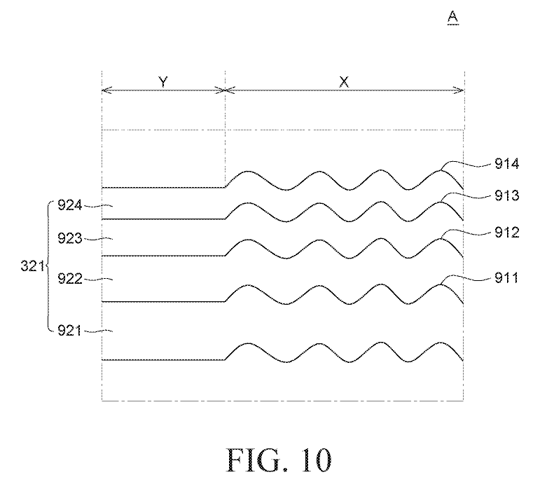

FIG. 10 is a view illustrating a layered structure of the first encapsulation layer in FIG. 9.

With reference to FIG. 10, the first encapsulation layer 321 may include at least two sub-encapsulation layer. For example, the first encapsulation layer 321 may include the first sub-encapsulation layer 921, the second sub-encapsulation layer 922, the third sub-encapsulation layer 923, and the fourth sub-encapsulation layer 924.

The first sub-encapsulation layer 921, the second sub-encapsulation layer 922, the third sub-encapsulation layer 923, and the fourth sub-encapsulation layer 924 may each be an inorganic insulation layer.

For example, the first sub-encapsulation layer 921 may include silicon nitride (SiNx), the second sub-encapsulation layer 922 and the third sub-encapsulation layer 923 may include silicon oxynitride (SiON), and the fourth sub-encapsulation layer 924 may include silicon oxide (SiOx). However, the present disclosure is not limited thereto.

A thickness of the first sub-encapsulation layer 921 may be larger than a thickness of each of the second sub-encapsulation layer 922, the third sub-encapsulation layer 923, and the fourth sub-encapsulation layer 924. A thickness of the fourth sub-encapsulation layer 924 disposed at the uppermost layer of the first encapsulation layer 321 may be larger than a thickness of the second sub-encapsulation layer 922 and a thickness of the third sub-encapsulation layer 923.

For example, the thickness of the fourth sub-encapsulation layer 924 may be 0.1 µm to 0.7 µm. In case that the thickness of the fourth sub-encapsulation layer 924 is less than 0.1 µm, the value of the centerline average roughness Ra of the plurality of protrusions 914 of the fourth sub-encapsulation layer 924 may decrease, and the spreading characteristics of the material of the second encapsulation layer 322 during the process of forming the second encapsulation layer 322 may deteriorate. In addition, in case that the thickness of the fourth sub-encapsulation layer 924 is more than 0.7 µm, the process of forming the fourth sub-encapsulation layer 924 may become difficult.

The value of the centerline average roughness Ra of the plurality of protrusions 914 of the fourth sub-encapsulation layer 924 may be 80 nm to 170 nm.

The first sub-encapsulation layer 921, the second sub-encapsulation layer 922, the third sub-encapsulation layer 923, and the fourth sub-encapsulation layer 924 may respectively include the plurality of protrusions 911, 912, 913, and 914 in area X and be structured to have flat top surfaces in area Y.

In this case, area X may be an area corresponding to a part of the third light-emitting area EA3 and a part of the non-light-emitting area NEA of the display device 100. Area Y may be an area corresponding to another part of the non-light-emitting area NEA.

The first encapsulation layer 321 may have the multilayer structure, as described above, thereby suppressing the permeation of moisture and oxygen into the light-emitting element ED. Further, the first encapsulation layer 321 may have the plurality of protrusions in area X, thereby suppressing a defect of the second encapsulation layer 322.

The embodiments of the present disclosure can also be described as follows:

According to an aspect of the present disclosure, there is provided a display device. The display device includes a substrate including a plurality of subpixels. The display device further includes a planarization layer disposed on the substrate and comprising an opening portion and a protruding portion. The display device further includes a first electrode disposed to cover a part of the opening portion and a part of the protruding portion. The display device further includes a bank disposed to expose a part of a top surface of the first electrode. The display device further includes an organic layer disposed on the top surface of the first electrode. The display device further includes a second electrode disposed on the bank and the organic layer. The display device further includes a first encapsulation layer disposed on the second electrode. The display device further includes a second encapsulation layer disposed on the first encapsulation layer. The protruding portion comprises an inclined portion and a flat portion extending from the inclined portion. The first encapsulation layer comprises a plurality of first protrusions disposed in an area that overlaps at least a part of the inclined portion and a part of the flat portion.

A top surface of the bank may include a plurality of second protrusions disposed in an area that overlaps at least a part of the inclined portion and a part of the flat portion.

A value of centerline average roughness Ra of the first protrusions may be smaller than a value of centerline average roughness Ra of the second protrusions.

A first width of the plurality of second protrusions with respect to the area, which overlaps the inclined portion, may be equal to or larger than a second width of the plurality of second protrusions with respect to the area that overlaps the flat portion.

A value of centerline average roughness Ra of the plurality of second protrusions, which overlap at least a part of the inclined portion, may be larger than a value of centerline average roughness Ra of the plurality of second protrusions that overlap a part of the flat portion.

The second protrusions may overlap the first electrode.

The second electrode may include a plurality of third protrusions disposed in an area that overlaps at least a part of the inclined portion and a part of the flat portion.

The organic layer may extend to a top surface of the bank, and the organic layer may include a plurality of fourth protrusions disposed in an area that overlaps at least a part of the inclined portion and a part of the flat portion.

The encapsulation layer may further include a third encapsulation layer disposed on the second encapsulation layer, and a top surface of the second encapsulation layer and a top surface of the third encapsulation layer each may have a flat shape.

The first encapsulation layer may include a plurality of sub-encapsulation layers.

The plurality of sub-encapsulation layers each may include a plurality of protrusions disposed in an area that overlaps at least a part of the inclined portion and a part of the flat portion.

A thickness of the sub-encapsulation layer, which is positioned at an uppermost end among the plurality of sub-encapsulation layers, may be 0.1 µm to 0.7 µm.

The plurality of first protrusions each may have a semicircular, semielliptical, or polygonal cross-sectional shape.

At least two of the plurality of first protrusions may have different cross-sectional shapes.

At least one of the plurality of subpixels may include a first light-emitting area, a second light-emitting area configured to surround the first light-emitting area, a third light-emitting area configured to surround the second light-emitting area and a non-light-emitting area configured to surround the third light-emitting area. At least some of the first protrusions may overlap at least a part of the third light-emitting area and at least a part of the non-light-emitting area.

Luminance of the first light-emitting area may be higher than luminance of each of the second and third light-emitting areas, and the luminance of the third light-emitting area may be higher than the luminance of the second light-emitting area.

According to another aspect of the present disclosure, there is provided a display device. The display device includes a substrate comprising a plurality of subpixels. The display device further includes a planarization layer disposed on the substrate and comprising an opening portion and a protruding portion. The display device further includes a first electrode disposed to cover the opening portion and the protruding portion. The display device further includes a bank disposed on a part of a top surface of the first electrode. The display device further includes an organic layer disposed on the first electrode. The display device further includes a second electrode disposed on the bank and the organic layer. The display device further includes a first encapsulation layer disposed on the second electrode. The display device further includes a second encapsulation layer disposed on the first encapsulation layer. At least one of the plurality of subpixels comprises a first light-emitting area, a second light-emitting area configured to surround the first light-emitting area, a third light-emitting area configured to surround the second light-emitting area and a non-light-emitting area configured to surround the third light-emitting area. The first encapsulation layer comprises a plurality of protrusions. At least some of the protrusions overlap at least a part of the third light-emitting area and at least a part of the non-light-emitting area.

The protruding portion may include an inclined portion and a flat portion extending from the inclined portion, and the plurality of protrusions may overlap at least a part of the inclined portion and a part of the flat portion.

The first light-emitting area may correspond to a part of the opening portion, the second light-emitting area may correspond to an area in which the opening portion and the bank overlap, and the third light-emitting area may correspond to the inclined portion of the opening portion.

A top surface of the bank may include a plurality of second protrusions disposed in an area that overlaps at least a part of the inclined portion and a part of the flat portion. The second electrode may include a plurality of third protrusions disposed in an area that overlaps at least a part of the inclined portion and a part of the flat portion.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate including a plurality of subpixels;
a planarization layer disposed on the substrate, the planarization layer comprising an opening portion and a protruding portion;
a first electrode disposed to cover the opening portion and a part of the protruding portion;
a bank disposed to expose a part of a top surface of the first electrode;
an organic layer disposed on the top surface of the first electrode;
a second electrode disposed on the bank and the organic layer;
a first encapsulation layer disposed on the second electrode; and
a second encapsulation layer disposed on the first encapsulation layer,
wherein the protruding portion comprises an inclined portion and a flat portion extending from the inclined portion, and
wherein the first encapsulation layer comprises a plurality of first protrusions disposed in an area that overlaps at least a part of the inclined portion and a part of the flat portion.

2. The display device of claim 1, wherein a top surface of the bank comprises a plurality of second protrusions disposed in an area that overlaps at least a part of the inclined portion and a part of the flat portion.

3. The display device of claim 2, wherein a value of a centerline average roughness Ra of the plurality of first protrusions is smaller than a value of a centerline average roughness Ra of the plurality of second protrusions.

4. The display device of claim 2, wherein a first width of the plurality of second protrusions with respect to a first part of the area that overlaps the inclined portion is equal to or larger than a second width of the plurality of second protrusions with respect to a second part of the area that overlaps the flat portion.

5. The display device of claim 2, wherein a value of a centerline average roughness Ra of the plurality of second protrusions that overlap at least a part of the inclined portion is larger than a value of a centerline average roughness Ra of the plurality of second protrusions that overlap a part of the flat portion.

6. The display device of claim 1, wherein the second electrode comprises a plurality of third protrusions disposed in an area that overlaps at least a part of the inclined portion and a part of the flat portion.

7. The display device of claim 1, wherein the organic layer extends to a top surface of the bank, and the organic layer comprises a plurality of fourth protrusions disposed in an area that overlaps at least a part of the inclined portion and a part of the flat portion.

8. The display device of claim 1, further comprising a third encapsulation layer disposed on the second encapsulation layer,
wherein each of a top surface of the second encapsulation layer and a top surface of the third encapsulation layer has a flat shape,
wherein the first encapsulation layer comprises a plurality of sub-encapsulation layers,
wherein each of the plurality of sub-encapsulation layers includes a plurality of protrusions disposed in an area that overlaps at least a part of the inclined portion and a part of the flat portion.

9. The display device of claim 1, wherein at least two of the plurality of first protrusions have different cross-sectional shapes.

10. The display device of claim 1, wherein at least one of the plurality of subpixels comprises:
a first light-emitting area;
a second light-emitting area surrounding the first light-emitting area;
a third light-emitting area surrounding the second light-emitting area; and
a non-light-emitting area surrounding the third light-emitting area,
wherein at least some of the plurality of first protrusions overlap at least a part of the third light-emitting area and at least a part of the non-light-emitting area, and
wherein a luminance of the first light-emitting area is higher than a luminance of each of the second light-emitting area and the third light-emitting area, and a luminance of the third light-emitting area is higher than a luminance of the second light-emitting area.

11. The display device of claim 1, wherein the bank is on the part of the top surface of the first electrode.

12. The display device of claim 10, wherein the first light-emitting area corresponds to a part of the opening portion, the second light-emitting area corresponds to an area in which the opening portion and the bank overlap, and the third light-emitting area corresponds to an inclined portion of the opening portion.

13. A light emitting device, comprising:
a first electrode;
a bank on a portion of the first electrode;
an organic layer on the first electrode, at least a part of the organic layer in direct contact with a part of the first electrode in an area where the bank exposes the first electrode;
a second electrode on the organic layer and the bank; and
one or more encapsulation layers on the second electrode,
wherein at least one of the bank, the organic layer, the second electrode, and the one or more encapsulation layers includes a plurality of protrusions positioned outside of the area where at least the part of the organic layer is in direct contact with the part of the first electrode.

14. The light emitting device of claim 13, wherein the one or more encapsulation layers include a first encapsulation layer on the second electrode and in direct contact with the second electrode, and
wherein the first encapsulation layer includes a first plurality of protrusions of the plurality of protrusions.

15. The light emitting device of claim 14, wherein the bank includes a second plurality of protrusions of the plurality of protrusions,
wherein the second electrode includes a third plurality of protrusions of the plurality of protrusions, and
wherein the organic layer includes a fourth plurality of protrusions of the plurality of protrusions.

16. The light emitting device of claim 15, wherein the one or more encapsulation layers further include a second encapsulation layer on the first encapsulation layer, the second encapsulation layer including a fifth plurality of protrusions of the plurality of protrusions,
wherein the one or more encapsulation layers further include a third encapsulation layer on the second encapsulation layer, the third encapsulation layer including a sixth plurality of protrusions of the plurality of protrusions, and
wherein the one or more encapsulation layers further include a fourth encapsulation layer on the third encapsulation layer, the fourth encapsulation layer including a seventh plurality of protrusions of the plurality of protrusions.

17. The light emitting device of claim 16, wherein each of the first encapsulation layer, the second encapsulation layer, the third encapsulation layer, and the fourth encapsulation layer overlaps a first area of the light emitting device and a second area of the light emitting device adjacent to the first area,
wherein each of the first plurality of protrusions, the fifth plurality of protrusions, the sixth plurality of protrusions, and the seventh plurality of protrusions are in the first area, and
wherein each of the first encapsulation layer, the second encapsulation layer, the third encapsulation layer, and the fourth encapsulation layer has a flat surface in the second area.

18. The light emitting device of claim 16, wherein a first thickness of the first encapsulation layer is larger than a second thickness of the second encapsulation layer, a third thickness of the third encapsulation layer, and a fourth thickness of the fourth encapsulation layer, and
wherein the fourth thickness of the fourth encapsulation layer is larger than the second thickness of the second encapsulation layer and the third thickness of the third encapsulation layer.

19. The light emitting device of claim 14, wherein the area where the bank exposes the first electrode is formed by a hole in the bank, and
wherein the first encapsulation layer includes the first plurality of protrusions in at least a portion of an area of the first encapsulation layer that surrounds an opening portion of the first encapsulation layer, the opening portion of the first encapsulation layer overlapping the hole.

20. The light emitting device of claim 19, wherein the one or more encapsulation layers further include a second encapsulation layer on the first encapsulation layer, and
wherein the second encapsulation layer is spread into the opening portion of the first encapsulation layer from a surface of the first encapsulation layer.
